(19) United States
(12) Patent Application Publication
(10) Pub. No.: US 2021/0357007 A1
(43) Pub. Date: Nov. 18, 2021

(54) DISPLAY PANEL

(71) Applicant: Wuhan China Star Optoelectronics Semiconductor Display Technology Co.,Ltd., Wuhan, Hubei (CN)

(72) Inventor: Xiaoxia Zhang, Wuhan, Hubei (CN)

(21) Appl. No.: 16/621,974

(22) PCT Filed: Apr. 15, 2019
(86) PCT No.: PCT/CN2019/082615

§ 371 Date: Dec. 12, 2019

(30) Foreign Application Priority Data
Dec. 13, 2018 (CN) 201811528546.9

(51) Int. Cl. G06F 1/18

(52) U.S. Cl. CPC G06F 1/189; G06F 1/181

(57) ABSTRACT

A display panel includes a base substrate, a plurality of binding terminals disposed at intervals on the organic layer, and an organic layer arranged on the base substrate. The organic layer includes a first boundary arranged in a non-display area of the display panel. The first boundary is arranged outside the binding terminal. A plurality of grooves in the organic layer are arranged in parallel along the first boundary. One or more groove is arranged between two of the adjacent binding terminals.

### BACKGROUND

### 1. Field of the Disclosure

The present disclosure relates to a field of display technology, and more particularly, to a display panel.

### 2. Description of the Related Art

The design of a flexible panel of the related art is that an inorganic layer and an organic layer are generally removed at the scribe line of the panel to ensure the quality of scribe and the convenience of the subsequent process. And outside the scribe line will retain the inorganic layer and the organic layer to protect the panel. In general, the inorganic layer is thin, which is not easy to produce the metallic residue at the edge. But, the thickness of the organic layer is relatively greater. After the organic layer is removed at the scribe line, the metal easily remains in the scribe line at the edge of the organic layer in the post-metallization process.

FIG. 1 is a top view of residual metal at the edge of the display panel of the related art. The display panel includes a base substrate 11′, an inorganic layer 12′, an organic layer 13′, a binding terminal 14′, and a signal terminal 15′. The binding terminal 14′ is arranged on the organic layer 13′. One terminal of the signal terminal 15′ is connected to the binding terminal 14′. The other terminal of the signal terminal 15′ is connected to the flexible circuit board or a driving chip. Since the organic layer 13′ is designed to be a continuous organic layer, the metallic residue is produced in the post-metallization process and a continuous residual metal 16′ is easy to be produced in the post-metallization process, resulting in the respective signal terminals 15′ connected through the residual metal 16′, thereby causing binding. Besides, a short circuit occurs between the signal terminals 15′, affecting the yield rate of the panel.

In the related art, the distance between the scribe line and the binding terminal at the edge of the panel is increased to ensure that the organic layer at the edge of the scribe line is located outside the signal terminal and to avoid the signal terminal from contacting the edge of the organic layer, thereby avoiding signal terminals from contacting the residual metal, which may cause a short circuit. However, this plan may cause lower bezels of the panel to become widened, thus affecting the layout of the entire motherboard, which is not conducive to the screen-to-body ratio of the display screen.

### SUMMARY

The present disclosure proposes a display panel to resolve the problem of the related art. In the display panel of the related art, an inorganic layer and an organic layer is removed on a scribe line, causing the inorganic layer to be generally thinner. The residual metal is not easy to be produced in the scribe line in the post-metallization process while the thickness of the organic layer is relatively thick so the scribe line of the organic layer is easy to produce the metallic residue in the post-metallization process. Thereby, a short circuit occurs between the signal terminals of the panel, causing a short circuit of different signals and the panel with a poor quality.

The present disclosure proposes a display panel defining a display area and a non-display area disposed outside the display area. The display panel comprises a base substrate, a plurality of binding terminals disposed at intervals on the organic layer and in the non-display area, an organic layer arranged on the base substrate, and an inorganic layer arranged between the organic layer and the base substrate. The organic layer comprises a first boundary arranged in the non-display area. The first boundary is arranged outside the binding terminal. A plurality of grooves in the organic layer are arranged in parallel along the first boundary. One or more groove is arranged between two of the adjacent binding terminals.

In some embodiment of the present disclosure, a plurality of holes are arranged on the organic layer. Each of the plurality of holes is configured to expose the corresponding binding terminal.

In some embodiment of the present disclosure, along a direction of the thickness of the base substrate, the groove penetrates the organic layer.

In some embodiment of the present disclosure, the groove comprises a first side and a second side. The first side and the second side face opposite.

In some embodiment of the present disclosure, the first side of the display panel is opposite to the second side of the organic layer. The second side of the display panel is arranged on the extended terminal of the groove.

In some embodiment of the present disclosure, two of the grooves are arranged at intervals between the two adjacent binding terminals.

In some embodiment of the present disclosure, the direction for the length of the groove is parallel to the direction for the binding terminal.

In some embodiment of the present disclosure, the second side of the groove aligns one side of the binding terminal which adjoins the display area.

In some embodiment of the present disclosure, the display panel further includes a plurality of signal terminals connected to the corresponding binding terminal.

The present disclosure proposes a display panel defining a display area and a non-display area disposed outside the display area. The display panel comprises a base substrate, a plurality of binding terminals disposed at intervals on the organic layer and in the non-display area, a plurality of signal terminals connected to the corresponding binding terminal, and an organic layer arranged on the base substrate. The organic layer comprises a first boundary arranged in the non-display area. The first boundary is arranged outside the binding terminal. A plurality of grooves in the organic layer are arranged in parallel along the first boundary. One or more groove is arranged between two of the adjacent binding terminals.

In some embodiment of the present disclosure, the display panel further includes an inorganic layer arranged between the organic layer and the base substrate.

In some embodiment of the present disclosure, a plurality of holes are arranged on the organic layer. Each of the plurality of holes is configured to expose the corresponding binding terminal.

In some embodiment of the present disclosure, along a direction of the thickness of the base substrate, the groove penetrates the organic layer.

In some embodiment of the present disclosure, the groove comprises a first side and a second side. The first side and the second side face opposite.

In some embodiment of the present disclosure, the first side of the display panel is opposite to the second side of the organic layer. The second side of the display panel is arranged on the extended terminal of the groove.

In some embodiment of the present disclosure, two of the grooves are arranged at intervals between the two adjacent binding terminals.

In some embodiment of the present disclosure, the direction for the length of the groove is parallel to the direction for the binding terminal.

In some embodiment of the present disclosure, the second side of the groove aligns one side of the binding terminal which adjoins the display area.

The present disclosure brings some benefits as follows: A display panel is proposed by the present disclosure. A plurality of grooves are arranged at the edge of the organic layer near the scribe line so that the edge of the organic layer is discontinuous, and further, the residual metal produced in the post-metallization process is discontinuous. In this way, the risk of the panel with a short circuit is effectively reduced, thereby increasing the yield rate of the panel.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a top view of a conventional display panel.

FIG. 2 illustrates a top view of a display panel according to a first embodiment of the present disclosure.

FIG. 3 is an enlarged diagram of an A area of the display panel as illustrated in FIG. 2.

FIG. 4 is a schematic diagram of the cross-sectional structure of the display panel with the residual metal in the scribe line in the post-metallization process.

FIG. 5 illustrates a top view of a display panel according to a second embodiment of the present disclosure.

FIG. 6 illustrates a top view of a display panel according to a third embodiment of the present disclosure.

FIG. 7 is a cross-sectional view of the display panel as illustrated in FIG. 6.

FIG. 8 illustrates a top view of a display panel according to a fourth embodiment of the present disclosure.

FIG. 9 illustrates a top view of a display panel according to a fifth embodiment of the present disclosure.

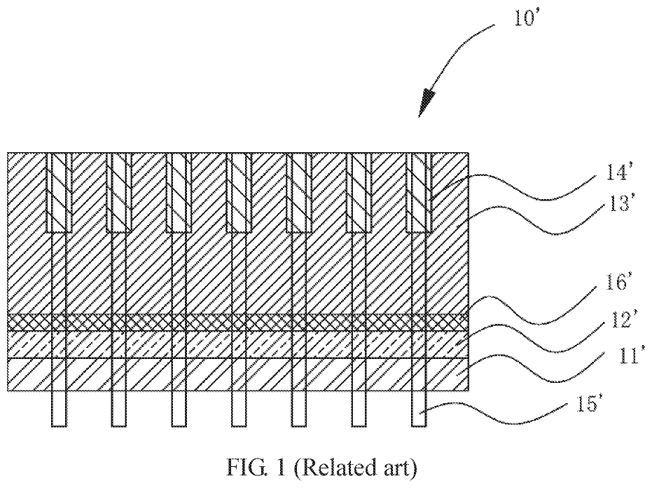

### DETAILED DESCRIPTION OF THE EMBODIMENTS

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

In the present disclosure, an inorganic layer and an organic layer are removed at a scribe line of a display of the related art. The inorganic layer is generally thinner, so it is not easy to produce residual metal in the scribe line in the post-metallization process. However, the thickness of the organic layer is relatively thick, so the residual metal is easily produced in the scribe line of the organic layer in the post-metallization process, resulting in the shortcut of a signal terminal of the panel, the shortcut of difficult signals, and further the panel with a poor quality. The present disclosure can deal with the defaults of the related art well.

### Embodiment 1

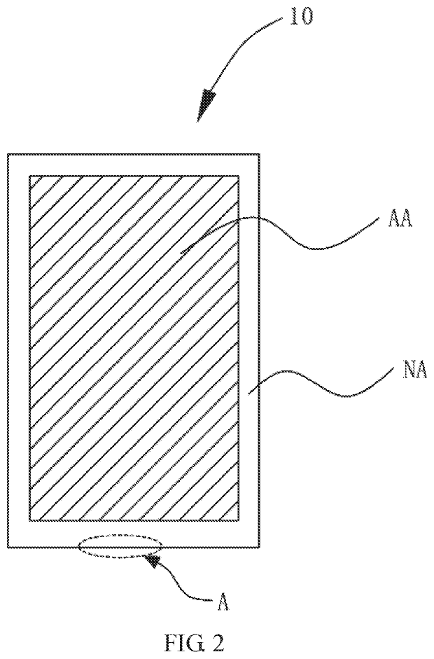

As FIG. 2 illustrates, a display panel 10 is adopted in the present embodiment. The display panel 10 defines a display area AA and a non-display area NA disposed outside the display area AA. In the present embodiment, the non-display area NA surrounds the display area AA. The display area AA is configured to show images. The non-display area NA is configured to accommodate a signal trace and other components for shield light.

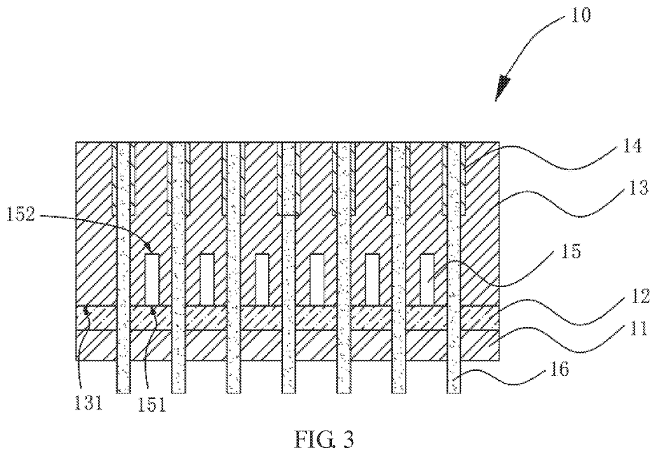

FIG. 3 is an enlarged diagram of an A area of the display panel 10 as illustrated in FIG. 2. FIG. 3 is a top view. The display panel 10 includes a base substrate 11, an inorganic layer 12, an organic layer 13, a plurality of binding terminals 14, and a plurality of signal terminals 16.

The inorganic layer 12 is disposed on the base substrate 11. The organic layer 13 is disposed on the inorganic layer 12. The plurality of binding terminals 14 are disposed in parallel on the organic layer 13.

A plurality of holes are arranged on the organic layer 13. Each of the plurality of holes are configured to expose the corresponding binding terminal 14. The binding terminal 14 is disposed in the non-binding display area NA. The binding terminal 14 is connected to a gate and a data driver arranged on the display panel 10. The binding terminal 14 is configured to receive a driving signal and transmit the driving signal to the corresponding driving circuit.

The number of the signal terminal 16 is the same as the number of the binding terminal 14. One terminal of the signal terminal 16 is connected to the binding terminal 14. The opposite terminal of the signal terminal 16 is connected to a flexible circuit board or a driving chip (not shown) of the display panel 10.

The organic layer 13 includes a first boundary 131 arranged in a non-display area NA. The first boundary 131 is arranged outside the binding terminal 14 and adjoins the scribe line of the display panel 10.

A plurality of grooves 15 in the organic layer 13 are arranged in parallel along the first boundary 131. The groove 15 includes a first side 151 and a second side 152. The first side 151 is opposite to the second side 152. The first side 151 aligns the first boundary 131 of the organic layer 13. The second side 152 is arranged on the extended terminal of the groove 15. The groove 15 is arranged in the non-display area NA. The groove 15 extends from the non-display area NA to the display area AA in a direction of longitudinal extension.

Along the direction of the thickness of the base substrate 11, the groove 15 penetrates the organic layer 13.

The direction for the length of the groove 15 is parallel to the direction for the binding terminal 14.

One or more groove 15 is arranged between two of the adjacent binding terminals 14. A groove 15 is arranged between every two of the adjacent binding terminals 14 in the present embodiment so that the organic layer 13 defines a discontinuous pattern and defines a discontinuous edge of the first boundary 131.

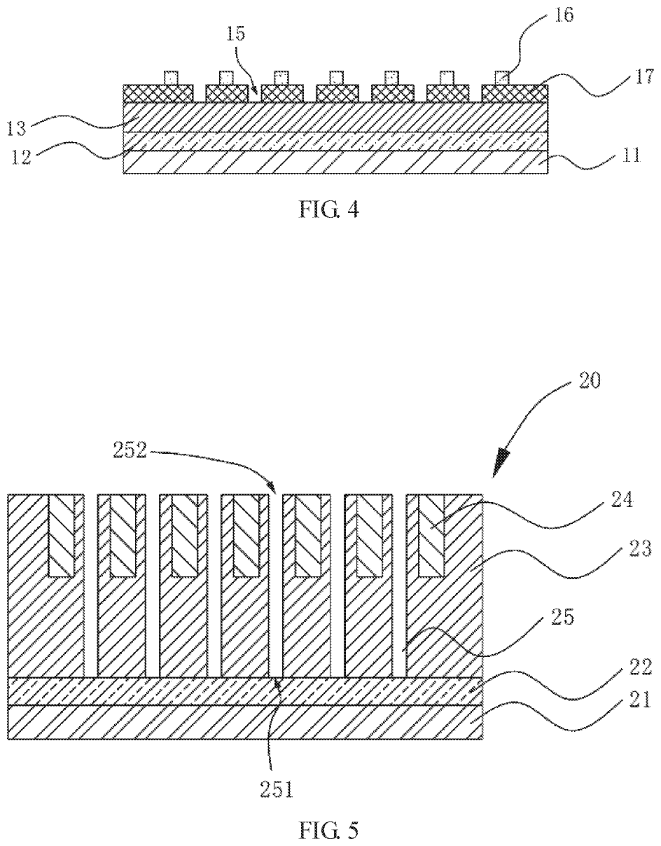

FIG. 4 is a schematic diagram of the cross-sectional structure of the display panel with the residual metal in the scribe line in the post-metallization process. While a display panel device is formed during the metal process, the entire surface of metal is deposited, and a metallic device is etched to form a patterned metallic device. The organic layer 13 in the scribe line needs to be removed, resulting in the edge of the organic layer 13 with residual metal easily and the residual metal in the continuous linear residue. In this embodiment, a plurality of grooves 15 are arranged on the first boundary 131 of the organic layer 13, and one or more one groove 15 is arranged between any two of the adjacent binding terminals 14. Therefore, the first boundary 131 of the organic layer 13 is a non-continuous edge, and the residual metal 17 in the metal process is non-continuous metal. Because no metal is connected between each of the two adjacent signal terminals 16, a short circuit does not occur.

The display panel 10 in the present embodiment is a flexible display panel. The base substrate 11 is a polyimide substrate but also may be another kind of flexible substrate.

The inorganic layer 12 is a silicon oxide layer or a silicon nitride layer. The inorganic layer 12 may be a plurality of stacked inorganic layers.

The width of the groove 15 is designed or determined based on the capacity of a person skilled in the art. The length of the groove 15 is determined based on actual needs. The length of the groove 15 may be extended to the binding terminal 14 and aligns the binding terminal 14.

The shape of an opening above the groove 15 is not determined; in other words, the opening may be rectangular, parallelogram, diamond, etc. The shape of the opening of the groove 15 is rectangular in the present embodiment.

The groove 15 may also be arranged on the edge of the inorganic layer 15. The groove 15 may be arranged on any film layer where the metal may remain easily in the present embodiment.

The adoption of the groove 15 can reduce the winding of the signal line, reduce the width of the non-display area NA below the display panel 10, increase the display area, and increase the screen-to-body ratio of the display screen.

### Embodiment 2

As FIG. 5 illustrates, a display panel 20 includes a base substrate 21, an inorganic layer 22, an organic layer 23, a plurality of binding terminals 24, and a plurality of signal terminals (not shown).

A plurality of grooves 25 is arranged on the organic layer 23. The groove 25 includes a first side 251 and a second side 252. The first side 251 and the second side 252 face opposite.

The difference between the second embodiment and the first embodiment lies in the length of the groove 25. The second side 252 of the groove 25 aligns one side of the binding terminal 24 which adjoins the display area.

The remaining components is the same as the components introduced in the first embodiment, which is not detailed here.

### Embodiment 3

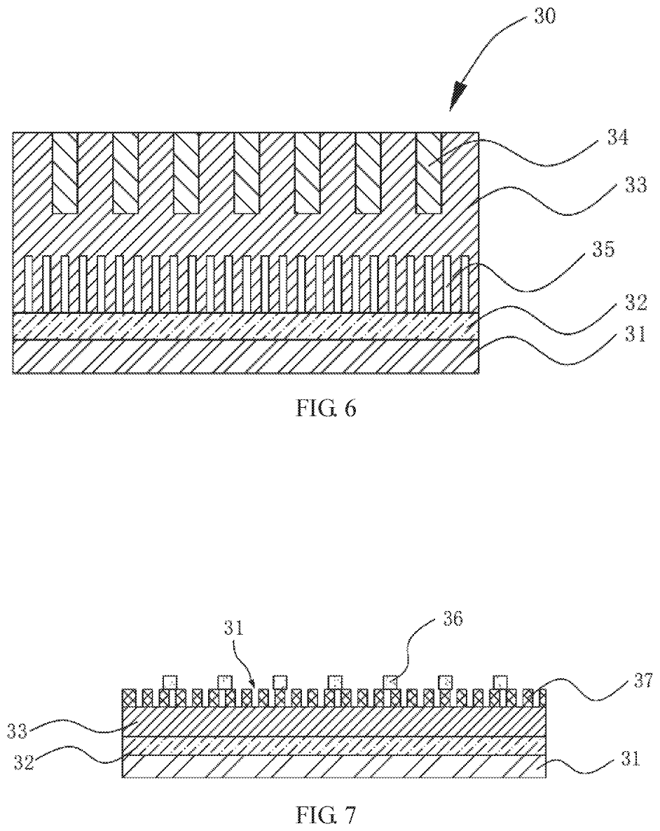

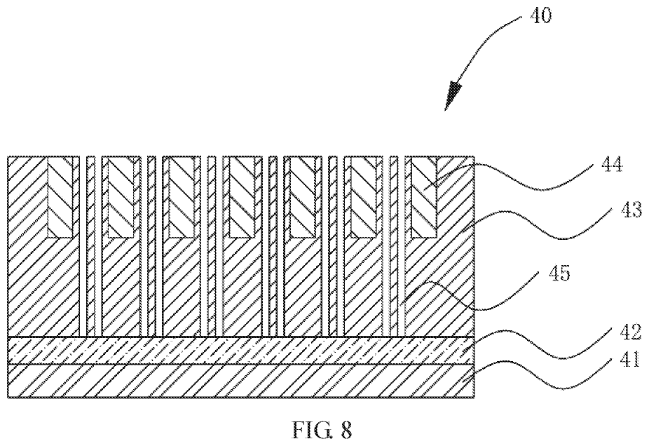

Please refer to FIG. 6 and FIG. 7. A display panel 30 includes a base substrate 31, an inorganic layer 32, an organic layer 33, a plurality of binding terminals 34, and a plurality of signal terminals 36 (not shown). A plurality of grooves 35 are arranged on the organic layer 33.

A great number of thin grooves 35 are adopted in the present disclosure so that the remaining metal 37 produced in the post-metallization process can form more discontinuous metal in small lumps, thereby reducing the risk of short circuit.

### Embodiment 4

Please refer to FIG. 8. A display panel 40 includes a base substrate 41, an inorganic layer 42, an organic layer 43, a plurality of binding terminals 44, and a plurality of signal terminals (not shown). A plurality of grooves 45 are arranged on the organic layer 43.

Different from the second embodiment, two grooves 45 are arranged at intervals between the two adjacent binding terminal 44 in the present embodiment reduce the risk of a short circuit.

Other structures are the same as the structure introduced in the second embodiment, which will not be repeated here.

### Embodiment 5

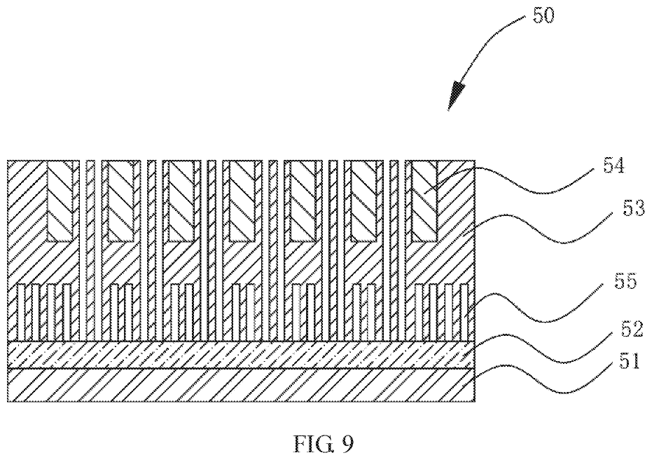

Please refer to FIG. 9 illustrating an effect diagram of the combination of the third embodiment and the fourth embodiment. A display panel 50 includes a base substrate 51, an inorganic layer 52, an organic layer 53, a plurality of binding terminals 54, and a plurality of signal terminals (not shown). A plurality of grooves 55 are arranged on the organic layer 53.

A groove 15 is arranged between two of the adjacent binding terminals 54. The extending terminal of the groove 55 between the adjacent binding terminals 54 aligns one side of the binding terminal 54 which adjoins the display area. The groove 55 is arranged in the area overlapping the binding terminal 54 in the extending direction.

The other structures can be referred to the third and fourth embodiments, which will not be repeated here.

A display panel is proposed by the present disclosure. A plurality of grooves are arranged at the edge of the organic layer near the scribe line so that the edge of the organic layer is discontinuous, and further, the residual metal produced in the post-metallization process is discontinuous. In this way, the risk of the panel with a short circuit is effectively reduced, thereby increasing the yield rate of the panel.

While the present invention has been described in connection with what is considered the most practical and preferred embodiments, it is understood that this invention is not limited to the disclosed embodiments but is intended to cover various arrangements made without departing from the scope of the broadest interpretation of the appended claims.

What is claimed is:

1. A display panel, defining a display area and a non-display area disposed outside the display area, comprising:
a base substrate;
a plurality of binding terminals, disposed at intervals on the organic layer and in the non-display area;
a plurality of signal terminals, connected to the corresponding binding terminal;
an organic layer, arranged on the base substrate; the organic layer comprising a first boundary arranged in the non-display area; the first boundary arranged outside the binding terminal; and
an inorganic layer, arranged between the organic layer and the base substrate;
wherein a plurality of grooves in the organic layer are arranged in parallel along the first boundary; one or more groove is arranged between two of the adjacent binding terminals.

2. The display panel of claim 1, wherein a plurality of holes are arranged on the organic layer; each of the plurality of holes are configured to expose the corresponding binding terminal.

3. The display panel of claim 1, wherein along a direction of the thickness of the base substrate, the groove penetrates the organic layer.

4. The display panel of claim 3, wherein the groove comprises a first side and a second side; the first side and the second side face opposite.

5. The display panel of claim 4, wherein the first side of the display panel is opposite to the second side of the organic layer; the second side of the display panel is arranged on the extended terminal of the groove.

6. The display panel of claim 4, wherein two of the grooves are arranged at intervals between the two adjacent binding terminals.

7. The display panel of claim 5, wherein the direction for the length of the groove is parallel to the direction for the binding terminal.

8. The display panel of claim 7, wherein the second side of the groove aligns one side of the binding terminal which adjoins the display area.

9. A display panel, defining a display area and a non-display area disposed outside the display area, comprising:
a base substrate;
a plurality of binding terminals, disposed at intervals on the organic layer and in the non-display area; and
an organic layer, arranged on the base substrate; the organic layer comprising a first boundary arranged in the non-display area; the first boundary arranged outside the binding terminal,
wherein a plurality of grooves in the organic layer are arranged in parallel along the first boundary, and one or more groove is arranged between two of the adjacent binding terminals.

10. The display panel of claim 9, further comprising an inorganic layer arranged between the organic layer and the base substrate.

11. The display panel of claim 9, wherein a plurality of holes are arranged on the organic layer; each of the plurality of holes are configured to expose the corresponding binding terminal.

12. The display panel of claim 9, wherein along a direction of the thickness of the base substrate, the groove penetrates the organic layer.

13. The display panel of claim 12, wherein the groove comprises a first side and a second side; the first side and the second side face opposite.

14. The display panel of claim 13, wherein the first side of the display panel is opposite to the second side of the organic layer; the second side of the display panel is arranged on the extended terminal of the groove.

15. The display panel of claim 13, wherein two of the grooves are arranged at intervals between the two adjacent binding terminals.

16. The display panel of claim 14, wherein the direction for the length of the groove is parallel to the direction for the binding terminal.

17. The display panel of claim 16, wherein the second side of the groove aligns one side of the binding terminal which adjoins the display area.

18. The display panel of claim 9, further comprising a plurality of signal terminals, wherein each of the signal terminals is connected to the corresponding binding terminal.
